(19) United States
(12) Patent Application Publication
(10) Pub. No.: US 2004/0048468 A1
(43) Pub. Date: Mar. 11, 2004

(54) Barrier metal cap structure on copper lines and vias

(75) Inventors: Wuping Liu, Singapore (SG); Beichao Zhang, Singapore (SG); Liang Choo Hsia, Singapore (SG)

Correspondence Address: GEORGE O. SAILE, 20 MCINTOSH DRIVE, POUGHKEEPSIE, NY, 12603, US

(73) Assignee: Chartered Semiconductor Manufacturing Ltd.

(21) Appl. No.: 10/238,767

(22) Filed: Sep. 10, 2002

(51) Int. Cl. H01L 21/44; C23C 14/32

(52) U.S. Cl. 438/687; 204/192.3; 204/192.17

(57) ABSTRACT

A new method is provided for the creation of damascene copper interconnects. A method is provided whereby created copper surfaces are capped with a layer of barrier material. With the cap structure of barrier material, the surface of the created copper interconnect is shielded against outside influences such as effects of processing chemicals. As a result of the creation of a cap of barrier material, conventional concerns of copper oxidation, copper back-sputtering and the like are eliminated.

### BACKGROUND OF THE INVENTION

(1) Field of the Invention

The invention relates to the fabrication of integrated circuit devices, and more particularly, to a method of creating copper damascene and dual damascene interconnects whereby negative effects of exposure of the copper surface are negated.

(2) Description of the Prior Art

In the creation of semiconductor devices, an important aspect of this creation is the interconnect metal that is provided between elements of semiconductor devices. Interconnect metal typically comprises metal conductive lines and vias that provide the interconnection of integrated circuits in semiconductor devices and/or the interconnections in a multilayer substrate over the surface of which semiconductor devices are mounted. One of the processes that is frequently used for the creation of conductive interconnects is the damascene and the dual damascene process. In fabricating Very and Ultra Large Scale Integration (VLSI and ULSI) circuits with the dual damascene process, a layer of insulating or dielectric material, comprising for instance silicon oxide, is patterned with several thousand openings. These openings form the pattern for the conductive lines and vias, which are filled at the same time with metal, such as typically aluminum but more recently copper. The pattern of conductive lines and vias serves to interconnect active and passive elements of an integrated circuit. The dual damascene process also is used to form multilevel conductive lines of metal, such as copper, in layers of insulating material, such as polyimide, using therewith multi-layer substrates over the surface of which semiconductor devices are mounted.

Damascene is an interconnection fabrication process in which grooves are formed in an insulating layer and filled with metal to form the conductive lines. Dual damascene is a multi-level interconnection process in which, in addition to forming the grooves of the single damascene process, conductive via openings also are formed. In the standard dual damascene process, the insulating layer is coated with a layer of photoresist. The coated layer of photoresist is first exposed through a first mask with an image pattern of the via openings, the via pattern is anisotropically etched in the upper half of the insulating layer. The photoresist now is second exposed through a second mask with an image pattern of conductive lines after the second exposure has been aligned with the first exposure pattern in order to encompass the via openings. In anisotropically etching the openings for the conductive lines in the upper half of the insulating material, the via openings that are previously created in the upper half of the insulating layer are simultaneously etched and replicated in the lower half of the insulating material. After the etching is complete, both the vias and line openings are filled with metal.

The dual damascene process is an improvement over the single damascene process since the dual damascene process permits the filling of both the conductive grooves and vias with metal at the same time, thereby eliminating processing steps. Although the standard damascene process offers a number of advantages over other processes for forming interconnections, it has a number of disadvantages. For instance, the dual damascene process requires two masking steps to form the pattern, a first mask for the vias and a second mask for the conductive lines. Further, the edges of the via openings in the lower half of the insulating layer, after the second etching, tend to be poorly defined because of the two etchings. In addition, since alignment of the two masks is critical in order for the pattern for the conductive lines to be over the pattern of the vias, a relatively large tolerance is provided resulting in via openings that do not extend the full width of the conductive line.

Copper is gaining increased use as an interconnect metal due to its relatively low cost and low resistivity. Copper however has a relatively large diffusion coefficient into a surrounding dielectric material such as silicon dioxide and silicon. Copper, which is used as an interconnect medium, therefore readily diffuses into the silicon dioxide layer causing the dielectric to become conductive and decreasing the dielectric strength of the silicon dioxide layer. Copper interconnects are therefore typically encapsulated by at least one diffusion barrier to prevent diffusion into the silicon dioxide layer. Copper further is well known to be very sensitive to surface exposure, most typically resulting in oxidation of the exposed copper surface.

The invention addresses concerns of creating copper interconnects and, more specifically, the negative impacts that are incurred by an exposed surface of copper interconnects.

U.S. Pat. No. 6,143,641 (Kitch) shows a dual damascene with cap layers.

U.S. Pat. No. 6,350,675 B1 (Chooi et al.) shows a dual damascene process with barrier layers.

U.S. Pat. No. 6,281,127 B1 (Shue) shows a self-passivation process for a dual damascene interconnect.

U.S. Pat. No. 6,274,499 (Gupta et al.) shows a cap over an interconnect.

U.S. Pat. No. 6,258,713 B1 (Yu et al.) discloses a dual damascene with a cap.

### SUMMARY OF THE INVENTION

A principle objective of the invention is to provide a method of creating damascene types copper interconnects whereby negative effects of surface exposure during the process of creating these interconnects are negated.

Another objective of the invention is to provide a method of creating copper damascene interconnects whereby the negative impact of in-line exposure to processing chemicals such as etching chemicals is negated.

Yet another objective of the invention is to provide a method of creating copper damascene interconnects whereby effects of copper back-sputtering are negated.

A still further objective of the invention is to provide a method of creating copper damascene interconnects whereby formation of copper surface irregularities such as copper hillocks is prevented.

In accordance with the objectives of the invention a new method is provided for the creation of damascene copper interconnects. A method is provided whereby created copper surfaces are capped with a layer of barrier material. With the cap structure of barrier material, the surface of the created copper interconnect is shielded against outside influences such as effects of processing chemicals. As a result of the creation of a cap of barrier material, conventional concerns of copper oxidation, copper back sputtering and the like are eliminated.

### BRIEF DESCRIPTION OF THE DRAWINGS

FIG. 1 shows a cross section of the surface of a semiconductor substrate over the surface of which copper vias and interconnect lines have been provided. The structure has been covered with a layer of barrier material.

FIG. 2 shows a cross section after a photoresist mask has been formed over the surface of the deposited layer of barrier material.

FIG. 3 shows a cross section after the layer of barrier material has been etched.

FIG. 4 shows a cross section after additional layers of semiconductor material have been deposited with the objective of creating a contact plug there-through.

FIG. 5 shows a cross section after a via opening has been etched through the deposited layers of semiconductor material.

FIG. 6 shows a cross-section after trench etch.

FIG. 7 shows a cross section after metal deposition and polishing, filling the created via and trench openings with metal.

### DESCRIPTION OF THE PREFERRED EMBODIMENTS

The creation of semiconductor devices having sub-micron and deep submicron device feature size has resulted in the conventional interconnect medium of aluminum being progressively replaced by copper or copper alloys including aluminum-copper (AlCu). For the creation of conductive interconnects, the single and dual damascene processes are frequently used for this purpose.

Applying state-of-the-art methods of creating single and dual damascene interconnects, the copper that is used as the conductive interconnect medium is readily exposed during processing to the fabrication environment, which in most applications comprises processing chemicals such as etchants.

As a result of this exposure of the copper surface, the copper reacts with the exposing substance, a reaction that has a negative impact on the exposed copper surface. In addition, this interaction between the copper and the environmentally present processing chemicals readily results in copper back-sputtering, causing the in this manner disbursed copper to be deposited on and to adhere to sidewalls of openings that have been created through layers of surrounding dielectric. This latter phenomenon results in degrading of the electrical performance of the created conductive interconnects since the surface between the surrounding dielectric and the deposited interconnect metal of copper is poorly defined. In addition, interaction between surrounding chemicals, for instance applied during a processing step of Chemical Vapor Deposition (CVD), readily leads to the formation of hillocks or surface irregularities in the exposed copper surface.

Copper is well known to readily oxidize when exposed to an oxygen containing environment such as air, to then remove the formed layer of copper oxide such steps as post-etch cleaning or pre-metallization treatment are frequently applied. These steps however do not assure that residual copper, that has formed over sidewalls of created via and trench openings, is also removed. In addition, the conventional step of pre-metallization treatment may further aggravate the situation by causing copper back sputtering.

To prevent all of the above highlighted negative aspects of creating single damascene and dual damascene copper interconnects, the invention provides for the creation of a cap layer of barrier material, as will now be explained in detail using FIGS. 1 through 7 for this purpose.

Referring first specifically to the cross section that is shown in FIG. 1, there is highlighted the cross section of a semiconductor substrate 10 over the surface of which are consecutively deposited a first layer 12 of dielectric such as Inter-Layer Dielectric (ILD), a first layer 14 of etch stop material, a first layer 15 of barrier material, a second layer 16 of dielectric such as Inter Metal Dielectric (IMD) and a second layer 18 of barrier material. Metal contacts or plugs or interconnects 11 have been created through the first layer 12 of ILD, metal plugs or interconnects 11 may comprise aluminum, copper, tungsten, and the like. Layer 14, more conventionally, is a first layer of etch stop material, such as a layer of silicon nitride.

It must be noted in the cross section that is shown in FIG. 1 that the surface of copper plugs or interconnects 13 is lower than or recessed (recess 19, FIG. 1) from the surface of layer 16 of dielectric by a measurable amount. This recess 19, preferred to have a height of between 30 and 80 Angstrom, is provided so that the thereover created layer of barrier material overlies and in this manner provides adequate protection to the surface of the copper plugs or interconnects 13.

A conventional layer 15 of barrier material has been deposited over sidewalls of openings created for the deposition of copper vias and interconnect lines 13 through the first layer 14 of etch stop material and second layer 16 of dielectric. The copper interconnects 13 may first, at a lower level, comprise vias created through the layer 14 of etch stop material after which interconnect trenches are created through the second layer 16 of IMD, the trenches being filled with copper.

Conventional processing may also be applied to remove all or part of the barrier layer 15 from the bottom of the openings created through the layers 14 and 16 of dielectric, this in order to improve contact resistance of the created copper interconnects 13. Since this is not germane to the invention, this aspect has not been highlighted in the cross section shown in FIG. 1.

Barrier layer is formed of a material selected from the group consisting of without however being limited thereto tungsten, Ti/TiN:W (titanium/titanium nitride:tungsten), titanium-tungsten/titanium or titanium-tungsten nitride/titanium or titanium nitride or titanium nitride/titanium, tantalum, tantalum nitride, tantalum silicon nitride, niobium, molybdenum, aluminum, aluminum oxide (AlₓO_{y}).

As a material for the layer 18 of barrier material is selected a material that is:

electrically conductive

copper compatible

isolation dielectric compatible

chemically stable and

resistant to interaction with processing chemicals.

For the layers 12 and 16 of dielectric can be used conventional materials used for the isolation of conductors from each other and from underlying conductive elements, a suitable dielectric being, for instance silicon dioxide (“oxide”, doped or undoped) or silicon nitride (“nitride”), silicon oxynitride, fluoropolymer, parylene, polyimide, tetra-ethyl-ortho-silicate (TEOS) based oxides, boro-phosphate-silicate-glass (BPSG), phospho-silicate-glass (PSG), boro-silicate-glass (BSG), oxidenitride-oxide (ONO), plasma enhanced silicon nitride (PSiNx), oxynitride. A low dielectric constant material, such as hydrogen silsesquioxane. HDP-FSG (high-density-plasma fluorine-doped silicate glass) is a dielectric that has a lower dielectric constant than regular oxide.

The most commonly used and therefore the preferred dielectrics of layers 12 and 16 are silicon dioxide (doped or undoped), silicon oxynitride, parylene or polyimide, spin-on-glass, plasma oxide or LPCVD oxide.

The same materials that have been highlighted above as possible materials for the layer 18 can also be considered for the layer 15 of barrier material. Barrier layer 15 is preferably about 100 and 500 Angstrom thick and more preferably about 300 Angstrom thick. Layer 18 of barrier material is preferably deposited to a thickness between about 50 and 150 Angstrom, filling recess 19, having a height between about 30 and 80 Angstrom, with the deposited barrier material.

Processes and processing conditions that are required for the creation of the structure that is shown in cross section in FIG. 1 are conventional processes with the exception of the creation of the layer 18 of barrier material. These conventional processes will therefore not be further highlighted at this time.

As an example of the creation of layer 18 of barrier material can be cited depositing titanium silicon nitride using PECVD in a temperature range of between 200 and 500 degrees C. to a thickness of between about 20 and 400 Angstrom. Preferably, the thickness of the barrier layer 18 is less than about 200 Angstrom.

For layer 14 of etch stop material can be selected a material that comprises a silicon component, for instance dielectrics such as silicon dioxide (“oxide”, doped or undoped) or silicon nitride (“nitride”), silicon oxynitride, silicon carbide (SiC), silicon oxycarbide (SIOC) and silicon nitro carbide (SiNC).

Layer 14 is preferably deposited using methods of LPCVD or PECVD or HDCVD or sputtering or High Density Plasma CVD (HDPCVD), deposited to a thickness between about 100 and 500 Angstrom.

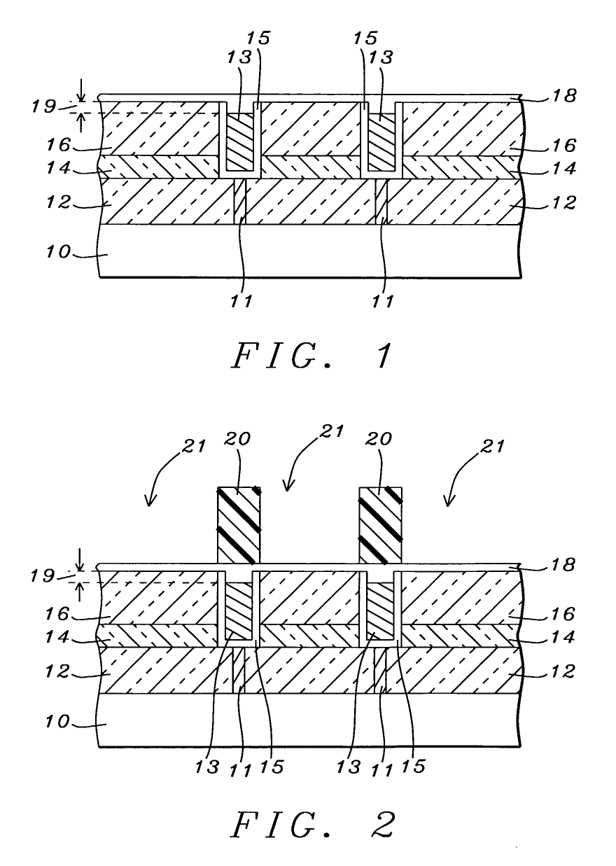

After the structure that is shown in cross section in FIG. 1 has been created, the deposited layer 18 of barrier material is now etched, for which purpose is created a patterned and developed layer 20 of photoresist overlying the surface of layer 18 of barrier material. This patterned and developed layer 20 of photoresist is shown in the cross section of FIG. 2, whereby the openings 21 that have been created through the layer 20 of photoresist are interspersed with the openings 21 that have originally been created for the openings of contact interconnects 13. It must thereby be noticed that the sidewalls for the openings that have originally been created for conductive interconnects 13 align with the sidewalls of the openings that are created through the layer 20 of photoresist. This in order to provide adequate protection over the surface of the copper interconnects 13 after the layer 18 of barrier material has been etched in accordance with the pattern created in the layer 20 of photoresist.

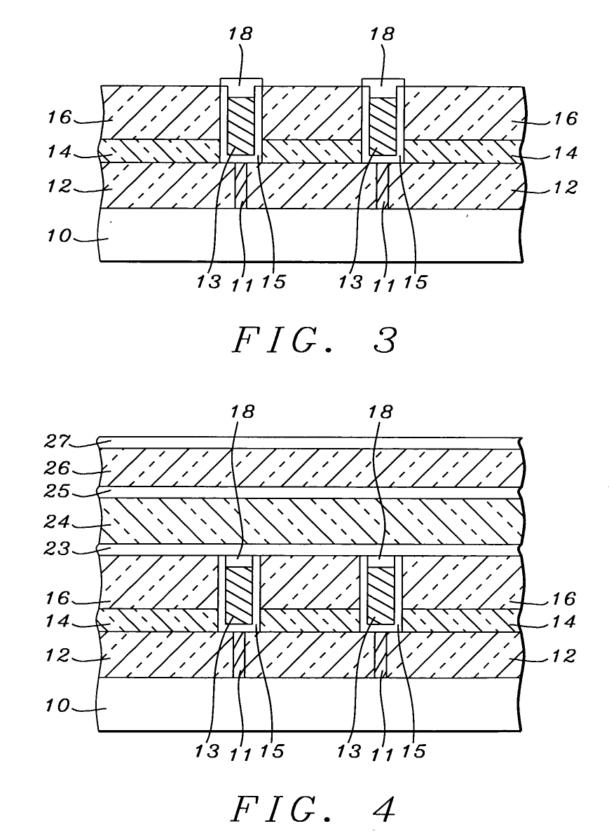

The layer 18 of barrier material, FIG. 3, is now etched in accordance with the pattern of the layer 20 of photoresist, leaving the barrier material in place overlying the copper interconnects 13.

In the cross section that is shown in FIG. 3 the photoresist mask 20 has been removed from above the surface of substrate 10 after the etch of layer 18 of barrier material has been completed. This removal of the photoresist mask can be achieved using conventional methods of ashing followed by a thorough surface clean.

The concept of the invention, which has been highlighted using the cross sections of FIGS. 1 through 3, that is the creation of a thin protective layer 18 of barrier material over the surface of created copped interconnects 13, is now further extended using FIGS. 4 through 7 for the completion of copper interconnects using the dual damascene process.

It must first be noted in the cross section that is shown in FIG. 4 that the layer 18 of barrier material that remains in place overlying the copper interconnects 13 does in this case, as opposed to the cross section shown in FIG. 3, not overly the layer 15 of barrier material that has been deposited over the inside surfaces of the openings that have been created for the creation of the copper interconnects 13. This cross section is readily obtained by applying a step of Chemical Mechanical Polishing (CMP) to the surface of the layer 18 of barrier material that is shown in cross section in FIG. 3.

This concept of creating the layer 18, as shown in cross section of FIG. 4, is further used for the extended explanation of the invention, an approach that can be validated by realizing that the layer 18 of barrier material that is shown in cross section in FIG. 4 continues to cover the surface of the copper interconnects 13.

The invention now proceeds with, FIG. 4, the deposition of additional layers of semiconductor material such as layers of dielectric, separated by layers of etch stop material, over the surface of the second layer 16 of dielectric. Specifically shown in the cross section of FIG. 4 are:

a second layer 23 of etch stop material (the first layer of etch stop material being layer 14)

a third layer 24 of dielectric (layer 12 being the first and layer 16 being the second layers of dielectric)

a third layer 25 of etch stop material

a fourth layer 26 of dielectric, and

a final and fourth layer 27 of etch stop material.

Key and of significant importance to the invention is, that during the deposition of the above highlighted layers of semiconductor material over the surface of the second layer 16 of dielectric, no copper surface is exposed and the created copper interconnects 13 therefore do not suffer any negative impact due to interaction with elements that are present in the processing environment.

Methods and processing conditions that are applied for the creation of the cross section that is shown in FIG. 4 follow conventional procedures after the cross section shown in FIG. 3 has been created and will therefore not be further detailed at this time.

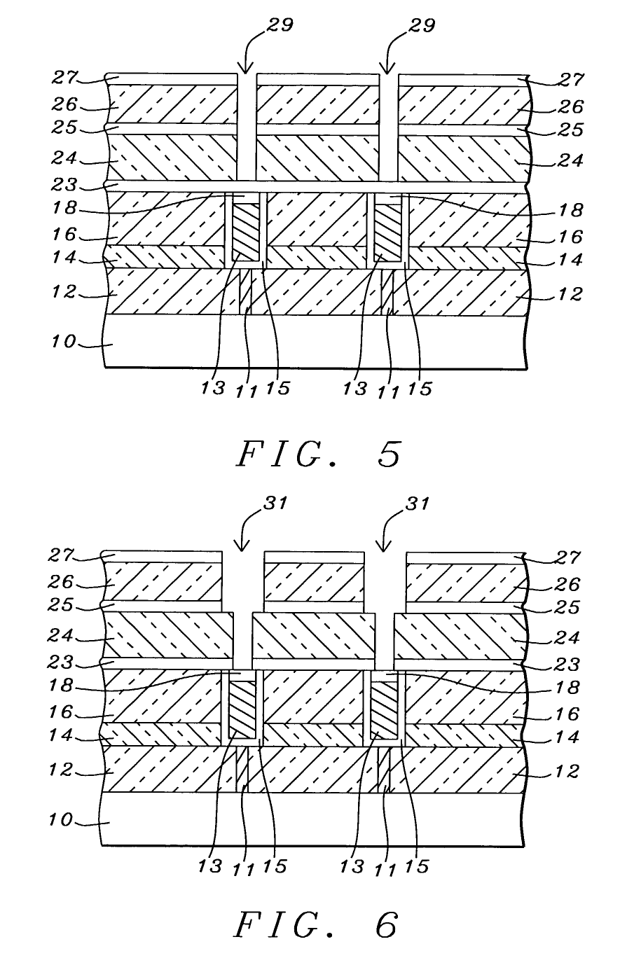

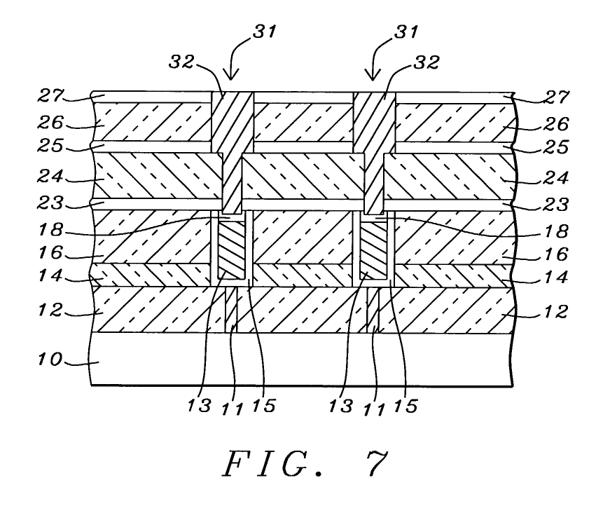

By now etching openings 29. FIG. 5, through the layers 24, 25, 26 and 27, openings 29 being aligned with the metal (preferably comprising copper) interconnects 11, the second layer 23 of etch stop material is exposed overlying the layers 18 of barrier material. By now, FIG. 6, etching a trench pattern through the layers 27, 26 and 25, and simultaneously transferring the via pattern 29, FIG. 5, through the second etch stop layer 23, the layer 18 of barrier material is exposed.

As part of the pattern transfer through the second layer 23 of etch stop material, the layer 18 of barrier material may also be affected, resulting in back-sputtering of the barrier material of layer 18. The in this manner back-sputtered barrier material (not shown in FIG. 6) deposits and adheres to the lower extremities of the openings 31, FIG. 6, where these lower extremities of openings 31 approach and are adjacent to the layers 18 of barrier material.

This deposition of barrier material over the above highlighted surface areas of openings 31 results in improved adhesion of the thereover deposited metal that is deposited to fill openings 31, facilitating this process of metal deposition.

In addition, the removal of the back-sputtered material from the surface of layers 18 reduces the thickness of these layers and as a consequence reduces the contribution of the barrier layer to the contact resistance of the contact interconnects created in openings 31, thereby reducing the contact resistance of the conductive interconnects created in openings 31.

The latter effects of reducing contact resistance of the contact interconnects and of improving metal adhesion to the sidewalls of openings 31 can be provided or enhanced by ion bombardment of the surface of the exposed layer 18 of barrier material. As an example of this latter process can be cited using Ar as sputtering ions at a temperature of about 25 to 150 degrees C. and a pressure of about 100 to 150 mTorr for a time duration of about 5 to 10 seconds, the sputter process being time controlled.

The cross section that is shown in FIG. 7 shows the filling 32 of the openings 31, FIG. 6, with a metal, preferably comprising copper, after the deposited layer of metal has been polished, using for instance methods of Chemical Mechanical Polishing, leaving copper interconnects 32 inside openings 31. The thickness of layers 18 in the cross section of FIG. 7 has been reduced by an amount and in accordance with the pattern of openings 31 in order to highlight the affect of the back-sputtering of the layer 18 of barrier material.

It must be pointed out, relating to the cross section that is shown in FIG. 7, that the openings through layers 23-27 for the creation of copper interconnects 32 therein can be lines with a layer of barrier material before these openings are filled with copper. This layer of barrier material has not been shown in the cross section of FIG. 7.

The summarize the invention:

copper points of interconnect are provided over the surface of a substrate, preferably embedded in a layer of dielectric

a layer of barrier material is deposited over the exposed surfaces of the copper interconnects, and

additional layers of copper interconnect are created aligned with the layers of barrier material overlying the surface of the copper points of interconnect.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

What is claimed is:

1. A method of creating copper interconnects, using steps of damascene processing, comprising steps of:
providing a semiconductor substrate, said substrate having been provided over the surface thereof with metal points of electrical contact, first copper interconnects having been created in a layer of dielectric overlying the surface of said substrate, said first copper interconnects being aligned with and overlying said metal points of electrical contact, the surface of said first copper interconnects being lower than the surface of said layer of dielectric by a measurable amount, causing first copper plug recesses;
creating a layer of barrier material over the surface of said first copper interconnects; and
completing creating copper interconnects aligned with said layer of first copper interconnects.

2. The method of claim 1, additionally said first copper interconnects being provided with a surrounding layer of barrier material.

3. The method of claim 2, additionally removing said surrounding layer of barrier material from a bottom surface of openings over inside surfaces of which said barrier material has been deposited.

4. The method of claim 3, said removing said surrounding layer of barrier comprising methods of argon sputtering.

5. The method of claim 4, said argon sputtering comprising using argon as sputtering ions at a temperature of about 25 to 150 degrees C. and a pressure of about 100 to 150 mTorr for a time duration of about 5 to 10 seconds, the sputter process being time controlled.

6. The method of claim 1, said creating a layer of barrier material over the surface of said first copper interconnects comprising steps of:
depositing a layer of barrier material over the surface of said layer of dielectric, thereby filling said first copper plug recesses with barrier material; and
patterning and etching said layer of barrier material, removing said barrier material from the surface of said layer of dielectric, leaving said barrier material inside said first copper plug recesses.

7. The method of claim 1, said completing creating copper interconnects aligned with said first copper interconnects comprising steps of:
depositing a least one stack of semiconductor material over the surface of said layer of dielectric, said at least one stack comprising:
(i) a first layer of etch stop material; and
(ii) a second layer of dielectric, deposited over the surface of said first layer of etch stop material;
patterning and etching said at least one stack of semiconductor material, creating damascene or dual damascene openings there-through that align with said first copper interconnects; and
filling said openings with copper, using methods of copper deposition followed by copper surface polishing, thereby creating second copper interconnects aligned with said first copper interconnects.

8. The method of claim 1, said layer of barrier material being deposited to a thickness between about 50 and 150 Angstrom.

9. The method of claim 1, said first copper plug recesses having a height between about 30 and 80 Angstrom.

10. A method of creating copper interconnects, using steps of damascene processing, comprising steps of:
providing a semiconductor substrate, said substrate having been provided over the surface thereof with metal points of electrical contact, first copper interconnects having been created in a layer of dielectric overlying the surface of said substrate, said first copper interconnects being aligned with and overlying said metal points of electrical contact, the surface of said first copper interconnects being lower than the surface of said layer of dielectric by a measurable amount, causing first copper plug recesses, said first copper plug recesses having a height of between about 30 and 80 Angstrom;
creating a layer of barrier material over the surface of said first copper interconnects; and
completing creating copper interconnects aligned with said first copper interconnects.

11. The method of claim 10, additionally said first copper interconnects being provided with a surrounding layer of barrier material.

12. The method of claim 11, additionally removing said surrounding layer of barrier material from a bottom surface of openings over inside surfaces of which said barrier material has been deposited.

13. The method of claim 12, said removing said surrounding layer of barrier comprising methods of argon sputtering.

14. The method of claim 13, said argon sputtering comprising using argon as sputtering ions at a temperature of about 25 to 150 degrees C. and a pressure of about 100 to 150 mTorr for a time duration of about 5 to 10 seconds, the sputter process being time controlled.

15. The method of claim 10, said creating a layer of barrier material over the surface of said first copper interconnects comprising steps of:
depositing a layer of barrier material over the surface of said layer of dielectric, thereby filling said first copper plug recesses with barrier material; and
patterning and etching said layer of barrier material, removing said barrier material from the surface of said layer of dielectric, leaving said barrier material inside said first copper plug recess.

16. The method of claim 10, said completing creating copper interconnects aligned with said layer of barrier material comprising steps of:
depositing a least one stack of semiconductor material over the surface of said layer of dielectric, said at least one stack comprising:
(i) a first layer of etch stop material; and
(ii) a second layer of dielectric, deposited over the surface of said first layer of etch stop material;
patterning and etching said at least one stack of semiconductor material, creating damascene or dual damascene openings there-through that align with said first copper interconnects; and
filling said openings with copper, using methods of copper deposition followed by copper surface polishing, thereby creating second copper interconnects aligned with said first copper interconnects.

17. The method of claim 10, said layer of barrier material being deposited to a thickness between about 50 and 150 Angstrom.

18. A method of creating copper interconnects, using steps of damascene processing, comprising steps of:
providing a semiconductor substrate, said substrate having been provided over the surface thereof with metal points of electrical contact, first copper interconnects having been created in a layer of dielectric overlying the surface of said substrate, said first copper interconnects being aligned with and overlying said metal points of electrical contact, the surface of said first copper interconnects being lower than the surface of said layer of dielectric by a measurable amount, causing first copper plug recesses;
creating a layer of barrier material over the surface of said first copper interconnects, said layer of barrier material being deposited to a thickness between about 50 and 150 Angstrom, filling said first copper plug recesses; and
completing creating copper interconnects aligned with said first copper interconnects.

19. The method of claim 18, additionally said first copper interconnects being provided with a surrounding layer of barrier material.

20. The method of claim 19, additionally removing said surrounding layer of barrier material from a bottom surface of openings over inside surfaces of which said barrier material has been deposited.

21. The method of claim 20, said removing said surrounding layer of barrier comprising methods of argon sputtering.

22. The method of claim 21, said argon sputtering comprising using argon as sputtering ions at a temperature of about 25 to 150 degrees C. and a pressure of about 100 to 150 mTorr for a time duration of about 5 to 10 seconds, the sputter process being time controlled.

23. The method of claim 18, said creating a layer of barrier material over the surface of said first copper interconnects comprising steps of:
depositing a layer of barrier material over the surface of said layer of dielectric, thereby filling said first copper plug recesses with barrier material; and
patterning and etching said layer of barrier material, removing said barrier material from the surface of said layer of dielectric, leaving said barrier material inside said first copper plug recesses.

24. The method of claim 18, said completing creating copper interconnects aligned with said first copper interconnects comprising steps of:
depositing a least one stack of semiconductor material over the surface of said layer of dielectric, said at least one stack comprising:
(i) a first layer of etch stop material; and
(ii) a second layer of dielectric, deposited over the surface of said first layer of etch stop material;
patterning and etching said at least one stack of semiconductor material, creating damascene or dual damascene openings there-through that align with said first copper interconnects; and
filling said openings with copper, using methods of copper deposition followed by copper surface polishing, thereby creating second copper interconnects aligned with said first copper interconnects.

25. The method of claim 18, said first copper plug recesses having a height between about 30 and 80 Angstrom.

26. A method of creating copper interconnects, using steps of damascene processing, comprising steps of:
providing a semiconductor substrate, said substrate having been provided over the surface thereof with metal points of electrical contact, first copper interconnects having been created in a layer of dielectric overlying the surface of said substrate, said first copper interconnects being aligned with and overlying said metal points of electrical contact, the surface of said first copper interconnects being lower than the surface of said layer of dielectric by a measurable amount, causing first copper plug recesses, said first copper plug recesses having a height between about 30 and 80 Angstrom;
creating a layer of barrier material over the surface of said first copper interconnects, said layer of barrier material being deposited to a thickness between about 50 and 150 Angstrom, filling said first copper plug recesses; and
completing creating copper interconnects aligned with said first copper interconnects.

27. The method of claim 26, additionally said first copper interconnects being provided with a surrounding layer of barrier material.

28. The method of claim 27, additionally removing said surrounding layer of barrier material from a bottom surface of openings over inside surfaces of which said barrier material has been deposited.

29. The method of claim 28, said removing said surrounding layer of barrier comprising methods of argon sputtering.

30. The method of claim 29, said argon sputtering comprising using argon as sputtering ions at a temperature of about 25 to 150 degrees C. and a pressure of about 100 to 150 mTorr for a time duration of about 5 to 10 seconds, the sputter process being time controlled.

31. The method of claim 26, said creating a layer of barrier material over the surface of said first copper interconnects comprising steps of:
depositing a layer of barrier material over the surface of said layer of dielectric, thereby filling said first copper plug recesses with barrier material; and
patterning and etching said layer of barrier material, removing said barrier material from the surface of said layer of dielectric, leaving said barrier material inside said first copper plug recesses.

32. The method of claim 26, said completing creating copper interconnects aligned with said layer of barrier material comprising steps of:
depositing a least one stack of semiconductor material over the surface of said layer of dielectric, said at least one stack comprising:
(i) a first layer of etch stop material; and
(ii) a second layer of dielectric, deposited over the surface of said first layer of etch stop material;
patterning and etching said at least one stack of semiconductor material, creating damascene or dual damascene openings there-through that align with said first copper interconnects; and
filling said openings with copper, using methods of copper deposition followed by copper surface polishing, thereby creating second copper interconnects aligned with said first copper interconnects.

33. A method of creating copper interconnect, comprising steps of:
providing a semiconductor substrate, said substrate having been provided with metal points of interconnect over the surface thereof;
depositing a first stack of layers of semiconductor material over the surface of said substrate, thereby including the surface of said metal points of interconnect provided over the surface of said substrate, said first stack of layers of semiconductor material comprising:
(i) a first layer of etch stop material; and
(ii) a second layer of dielectric deposited over the surface of said first layer of etch stop material;
patterning and etching said first stack of semiconductor material, creating first openings there-through aligned with said metal points of interconnect provided over the surface of said substrate;
depositing a first layer of barrier material over the surface of said first stack of layers of semiconductor material, thereby including inside surfaces of said first openings;
filling said first openings with copper, providing first copper interconnects, the surface of said first copper interconnects being lower than the surface of said first stack of layers of semiconductor material by a measurable amount, causing first copper plug recesses;
removing said first layer of barrier material from the surface of said first stack of layers of semiconductor material;
depositing a second layer of barrier material over the surface of said first stack of layers of semiconductor material, thereby filling said first copper plug recesses;
patterning and etching said second layer of barrier material, leaving said second layer of barrier material in place in said first copper plug recesses; and
completing said copper interconnect by creating second copper interconnects aligned with said second layer of barrier material in said first copper plug recesses using methods of dual damascene processing.

34. The method of claim 33, additionally removing said first layer of barrier material from a bottom surface of said first openings.

35. The method of claim 34, said removing said first layer of barrier material comprising methods of argon sputtering.

36. The method of claim 35, said argon sputtering comprising using argon as sputtering ions at a temperature of about 25 to 150 degrees C. and a pressure of about 100 to 150 mTorr for a time duration of about 5 to 10 seconds, the sputter process being time controlled.

37. The method of claim 33, said patterning and etching said second layer of barrier material comprising steps of:
depositing a second layer of barrier material over the surface of said first stack of semiconductor material, thereby filling said first copper plug recesses with a second layer of barrier material; and
patterning and etching said second layer of barrier material, removing said second layer of barrier material from the surface of said layer of dielectric, leaving said second layer of barrier material inside said first copper plug recesses.

38. The method of claim 33, said completing said copper interconnect comprising steps of:
depositing a least one second stack of semiconductor material over the surface of said first stack of semiconductor material, said at least one second stack comprising:
(i) a first layer of etch stop material; and
(ii) a second layer of dielectric, deposited over the surface of said first layer of etch stop material;
patterning and etching said at least one second stack of semiconductor material, creating dual damascene openings therethrough that align with said first copper interconnects; and
filling said dual damascene openings with copper, using methods of copper deposition followed by copper surface polishing, thereby creating second copper interconnects aligned with said first copper interconnects.

39. The method of claim 33, said second layer of barrier material being deposited to a thickness between about 50 and 150 Angstrom.

40. The method of claim 33, said first copper plug recesses having a height between about 30 and 80 Angstrom.

41. A method of creating copper interconnect, comprising steps of:
providing a semiconductor substrate, said substrate having been provided with metal points of interconnect over the surface thereof;
depositing a first stack of layers of semiconductor material over the surface of said substrate, thereby including the surface of said metal points of interconnect provided over the surface of said substrate, said first stack of layers of semiconductor material comprising:
(i) a first layer of etch stop material; and
(ii) a second layer of dielectric deposited over the surface of said first layer of etch stop material;
patterning and etching said first stack of semiconductor material, creating first openings there-through aligned with said metal points of interconnect provided over the surface of said substrate;
depositing a first layer of barrier material over the surface of said first stack of layers of semiconductor material, thereby including inside surfaces of said first openings;
filling said first openings with copper, providing first copper interconnects, the surface of said first copper interconnects being lower than the surface of said first stack of layers of semiconductor material by a measurable amount, causing first copper plug recesses, said first copper plug recesses having a height between about 30 and 80 Angstrom;
removing said first layer of barrier material from the surface of said first stack of layers of semiconductor material;
depositing a second layer of barrier material over the surface of said first stack of layers of semiconductor material, thereby filling said first copper plug recesses, said second layer of barrier material being deposited to a thickness between about 50 and 150 Angstrom;
patterning and etching said second layer of barrier material, leaving said second layer of barrier material in place in said first copper plug recesses; and
completing said copper interconnect by creating second copper interconnects aligned with said second layer of barrier material in said first copper plug recesses using methods of dual damascene processing.

42. The method of claim 41, additionally removing said first layer of barrier material from a bottom surface of said first openings.

43. The method of claim 42, said removing said first layer of barrier material comprising methods of argon sputtering.

44. The method of claim 43, said argon sputtering comprising using argon as sputtering ions at a temperature of about 25 to 150 degrees C. and a pressure of about 100 to 150 mTorr for a time duration of about 5 to 10 seconds, the sputter process being time controlled.

45. The method of claim 41, said patterning and etching said second layer of barrier material comprising steps of:
depositing a second layer of barrier material over the surface of said first stack of semiconductor material, thereby filling said first copper plug recesses with a second layer of barrier material; and
patterning and etching said second layer of barrier material, removing said second layer of barrier material from the surface of said layer of dielectric, leaving said second layer of barrier material inside said first copper plug recesses.

46. The method of claim 41, said completing said copper interconnect comprising steps of:
depositing a least one second stack of semiconductor material over the surface of said first stack of semiconductor material, said at least one second stack comprising:
(i) a first layer of etch stop material; and
(ii) a second layer of dielectric, deposited over the surface of said first layer of etch stop material;
patterning and etching said at least one second stack of semiconductor material, creating dual damascene openings therethrough that align with said first copper interconnects; and
filling said dual damascene openings with copper, using methods of copper deposition followed by copper surface polishing, thereby creating second copper interconnects aligned with said first copper interconnects.

47. The method of claim 7, whereby said second copper interconnects aligned with said first copper interconnects are additionally surrounded by a layer of barrier material.

48. The method of claim 16, whereby said second copper interconnects aligned with said first copper interconnects are additionally surrounded by a layer of barrier material.

49. The method of claim 24, whereby said second copper interconnects aligned with said first copper interconnects are additionally surrounded by a layer of barrier material.

50. The method of claim 32, whereby said second copper interconnects aligned with said first copper interconnects are additionally surrounded by a layer of barrier material.

51. The method of claim 41, whereby said second copper interconnects aligned with said first copper interconnects are additionally surrounded by a layer of barrier material.

52. The method of claim 46, whereby said second copper interconnects aligned with said first copper interconnects are additionally surrounded by a layer of barrier material.
